(19) United States
(12) Patent Application Publication
(10) Pub. No.: US 2009/0053021 A1
(43) Pub. Date: Feb. 26, 2009

(54) Semiconductor manufacturing apparatus

(76) Inventors: Norichika Yamagishi, Toyama (JP); Sadao Hisakado, Toyama (JP)

Correspondence Address: KRATZ, QUINTOS & HANSON, LLP, 1420 K Street, N.W., Suite 400, WASHINGTON, DC, 20005, US

(21) Appl. No.: 11/887,111

(22) PCT Filed: Mar. 28, 2006
(86) PCT No.: PCT/JP2006/306220

§ 371 Date: Apr. 22, 2008

(30) Foreign Application Priority Data
Mar. 29, 2005 (JP) 2005-095129

(51) Int. Cl. H01L 21/677

(52) U.S. Cl. 414/222.02; 414/147; 414/806

(57) ABSTRACT

A semiconductor manufacturing apparatus comprises a substrate transfer device for transferring a substrate, a substrate detector unit including a light emitter unit for emitting light onto the substrate and a light receiver unit for receiving the light to detect the substrate transferred by the substrate transfer device, and a controller for receiving data on the received light quantity from the light receiver unit. Multiple mutually non-overlapping light quantity ranges are pre-registered in the controller, and when light emitted from the light emitter unit reaches the light receiver unit by way of the substrate, the controller identifies which of the pre-registered light quantity ranges is the received light quantity, and outputs a command according to the identified light quantity range.

### TECHNICAL FIELD

The present invention relates to a semiconductor manufacturing apparatus, and relates in particular to technology for identifying the type of substrate and is effective for use in diffusing dopant elements or forming CVD films such as metallic films and insulation films on semiconductor wafers (hereafter called wafers) on which are formed semiconductor integrated circuits including semiconductor devices in methods for example for manufacturing semiconductor integrated circuit devices (hereafter called IC).

### BACKGROUND ART

In wafers used in methods for manufacturing ICs, a notch (reference position indicator) is formed on one spot on the wafer edge for indicating the peripheral position of the circular wafer itself and the orientation of the crystal within the wafer.

The notch is cut in a small and narrow V shape on the wafer periphery.

The semiconductor manufacturing apparatus that diffuses dopant elements or forms the CVD film on the wafer in the IC manufacturing method usually contains a wafer positioning device that detects the notch formed on the wafer and aligns the position along the periphery.

Wafer positioning devices of the background art are designed to detect the notches on both glass wafers that are transparent and silicon wafers that are not transparent, by utilizing a sensor including a transmission type detector, a reflective type detector and light source.

See for example, patent document 1.
Patent document 1: Japanese Patent Non-Examined Publication No. 2003-289097

### DISCLOSURE OF INVENTION

### Problems to be Solved by Invention

However, the aforementioned wafer positioning devices were unable to recognize the wafer type, causing the problem that if the operator entered the wrong wafer type information in the controller of the semiconductor manufacturing apparatus, then all the wafers were rendered defective.

The present invention has the object of providing a semiconductor manufacturing apparatus capable of identifying the type of wafer.

### Means to Solve the Problems

Typical aspect for the invention as disclosed in this specification is given as follows.

(1) A semiconductor manufacturing apparatus comprising:

a substrate transfer device for transferring a substrate;

a substrate detector unit including a light emitter unit for emitting light onto the substrate and a light receiver unit for receiving the light to detect the substrate transferred by the substrate transfer device; and

a controller for receiving the received light quantity data from the light receiver unit, wherein

multiple, mutually non-overlapping light quantity ranges are pre-registered in the controller, and when light emitted from the light emitter unit reaches the light receiver unit by way of the substrate, the controller identifies which of the pre-registered light quantity ranges is the received light quantity, and outputs a command according to the identified light quantity range.

### EFFECT OF INVENTION

According to the first aspect (1), whether substrates transferred by the substrate transfer device are non-transparent substrates or transparent substrates or semi-transparent substrates can be identified so that the correct processing matching each substrate can be performed.

### BRIEF DESCRIPTION OF DRAWINGS

FIG. 1 is a perspective view showing the batch type CVD apparatus of one embodiment of the present invention;

FIG. 2 is a fragmentary abbreviated perspective view showing the wafer positioning device;

FIG. 3 is a fragmentary abbreviated frontal view of that device;

FIG. 4 is a fragmentary abbreviated side cross sectional view showing the transmission type sensor section of that device;

FIG. 5 is a fragmentary abbreviated side cross sectional view showing the reflective type sensor section of that device;

FIG. 6 is a block view showing the controller;

FIG. 7 is a flow chart for illustrating the wafer identification process;

### BEST MODE FOR CARRYING OUT THE INVENTION

An embodiment of the present invention is described next while referring to the drawings.

In the embodiment, the semiconductor manufacturing apparatus of the present invention is a batch type vertical diffusion CVD apparatus (hereafter called batch type CVD apparatus), utilized in the process for diffusing dopant elements or forming CVD films such as metallic films and insulation films on the wafer in IC manufacturing methods.

Carriers for transporting wafers in the batch type CVD apparatus of this embodiment utilize a FOUP (front opening unified pod, hereafter called pod). This pod is formed in a three-dimensional box shape with one open side, and a freely detachable cap is mounted on the open side.

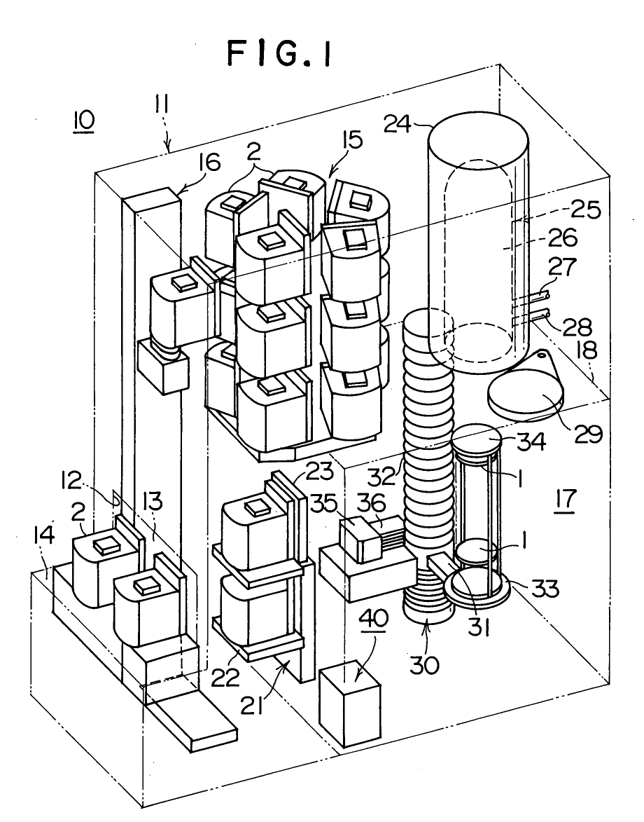

This batch type CVD apparatus 10 includes a case 11 formed in a rectangular, parallelpiped box shape from section steel or steel plate as shown by the imaginary lines in FIG. 1.

A pod load/unload opening 12 is formed in the frontal wall of the case 11 so as to penetrate through the inner-outer portions of the case 11. A front shutter 13 opens and closes the pod load/unload opening 12.

A pod stage 14 is mounted just prior to the pod load/unload opening 12 at the frontal wall of the case 11 as shown in FIG. 1. The pod stage 14 mounts the pod 2 for storing wafers 1 and aligns the position of the pod 2.

An inter-process transfer device (not shown in drawing) loads the pod 2 on the pod stage 14, and also unloads the pod 2 from the pod stage 14.

A rotating pod rack 15 is mounted on the upper section at approximately the center along the forward/rear within the case 11. The rotating pod rack 15 is structured so as to store multiple pods 2.

In other words, the rotating pod rack 15 contains a support pillar erected vertically on the standby chamber case described later on and rotated intermittently on a horizontal plane and; multiple shelf plates supported outward toward the periphery at each position on the upper-mid-lower stages on the support pillar. The multiple shelf plates each hold one pod 2.

A pod transfer device 16 is installed between the rotating pod rack 15 and the pod stage 14 within the case 11. The pod transfer device 16 transfers the pod 2 between the rotating pod rack 15 and the pod stage 14; and between the rotating pod rack 15 and the mounting stand for the pod opener described later on.

A standby chamber 17 for storing the boat as described later on and keeping in a stand-by condition is formed in a standby chamber case 18, opposite the pod stage 14 in the interior of the case 11. The standby chamber 17 is constructed as an airtight chamber (normally airtight structure capable of withstanding approximately atmospheric pressure) with proper gas sealing.

Though not shown in the drawing, a gas feed pipe and an exhaust pipe are respectively connected to the standby chamber 17 within the standby chamber case 18, and respectively supply and exhaust nitrogen gas.

A pair of wafer load/unload openings are formed on the frontal wall of the standby chamber case 18, arrayed perpendicularly on an upper and lower two stages for loading/unloading of wafers into/from the standby chamber 17. A pair of pod openers 21, 21 are respectively installed at the wafer load/unload openings on the upper/lower stage.

The pod openers 21 each contain a mounting stand 22 for mounting the pod 2, and a cap fitter/remover mechanism 23 for installing or removing the cap of the pod 2 mounted on the mounting stand 22. The cap fitter/remover mechanism 23 installs or removes the cap on the pod 2 loaded on the mounting stand 22. It serves to open or close the wafer load/unload opening of the pod 2.

A heater unit 24 is installed perpendicularly in the standby chamber case 18. A cylindrical process tube 25 open on the bottom end and sealed on the top end is installed concentrically inside the heater unit 24. The heater unit 24 heats a process chamber 26 formed in the hollow cylindrical section of the process tube 25.

A gas feed pipe 27 for supplying purge gas and material gas into the process chamber 26 and an exhaust pipe 28 for drawing a vacuum in the process chamber 26 are connected to the process tube 25.

A shutter 29 opens and shuts the bottom end opening of the process tube 25.

A boat elevator 30 is installed in the standby chamber 17 for raising and lowering the boat.

Though not shown in detail in the drawing, the boat elevator 30 contains a feed screw shaft erected perpendicularly and supported for free rotation, a motor for rotating the feed screw shaft forward or reverse, an arm 31 whose threads engage with the threads of the feed screw shaft for free rising/lowering, and a bellows 32 for covering the feed screw shaft.

A ball screw mechanism is utilized in the thread engaging section for the feed screw shaft and the arm 31 in order to obtain satisfactory backlash and movement during rising and lowering.

A seal cap 33 is installed horizontally on the tip of the arm 31 on the boat elevator 30. Besides sealing the bottom end opening of the process tube 25, the seal cap 33 perpendicularly supports a boat 34.

The boat 34 contains multiple (in this embodiment, 3 pieces) wafer (substrate) support members. Multiple (for example, approximately 50 to 150 pieces) of wafers 1 are horizontally supported by the boat 34 while arrayed around that center. The boat 34 is loaded into and unloaded from the process chamber 26 of the process tube 25 along with the rising/lowering of the seal cap 33 by the boat elevator 30.

A wafer transfer device 35 is installed in the standby chamber 17 for charging and discharging of the wafers 1 into/from the boat 34. This wafer transfer device 35 contains multiple (in this embodiment, 5 pieces) tweezers 36 for supporting the wafers 1 from the bottom. These tweezers 36 are installed horizontally at equally spaced intervals.

The wafer transfer device 35 moves five tweezers 36 in three dimensions so that five wafers 1 at a time are transferred between the pod 2 and the boat 34.

A wafer positioning device 40 is installed on one flank on the side opposite the boat 34 of the wafer transfer device 35 within the standby chamber 17 as shown in FIG. 1.

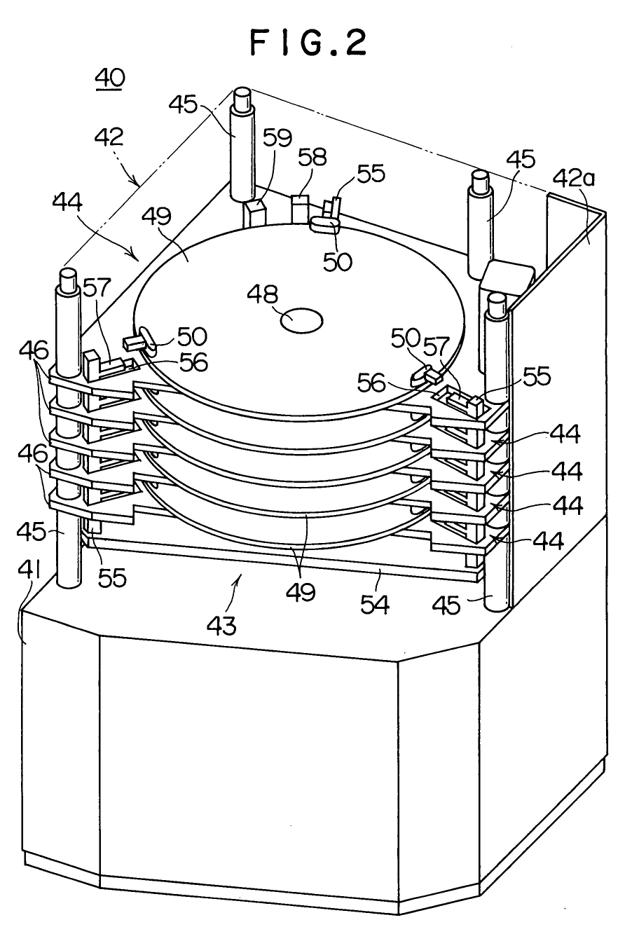

The structure of the wafer positioning device 40 of this embodiment is described next while referring to FIG. 2 onward.

As shown in FIG. 2, the wafer positioning device 40 contains a machine stand 41 rendered in a box shape with a horizontal upper surface. An enclosure plate 42a (only a portion is shown in the drawing) forms a case 42 above the machine stand 41. One side of the case 42 is widely open and this open side forms a wafer load/unload opening 43.

A total of five notch detectors 44 for detecting the notch 1a of the wafer 1 rotating inside the case 42, are arrayed vertically.

In other words, a total of four support poles 45, 45, 45, 45 are erected perpendicularly and affixed on the sides on the upper surface of the machine stand 41. A total of five shelf plates 46, 46, 46, 46, 46 are installed horizontally at equally spaced intervals vertically among the four support poles 45.

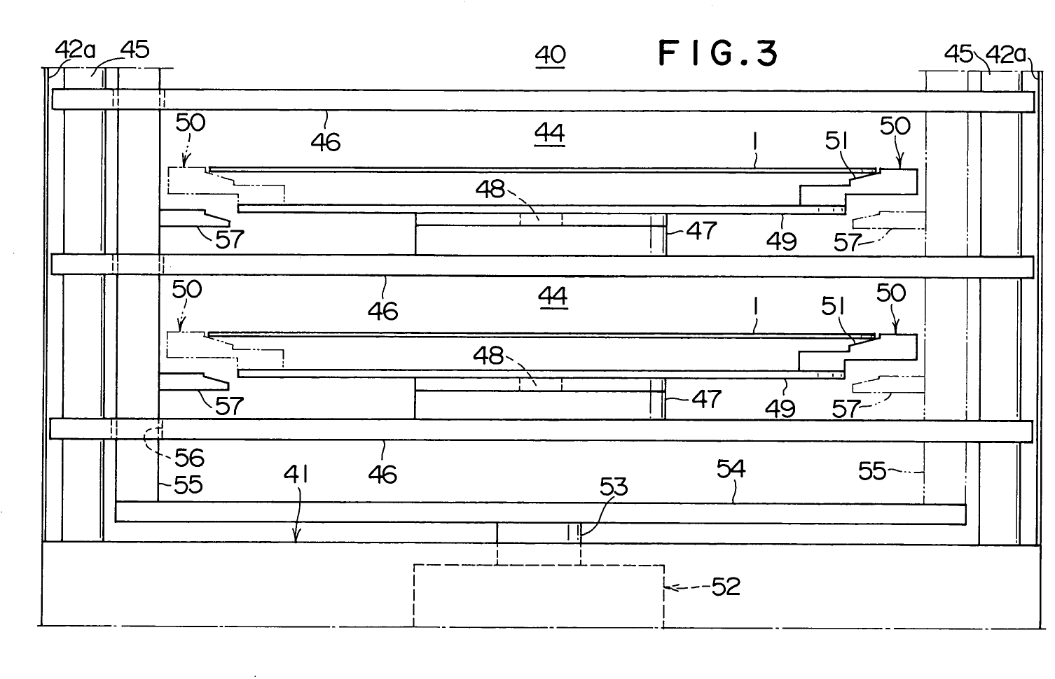

As shown in FIG. 3, one motor 47 is mounted on each shelf plate 46 and the rotating shafts 48 are each arranged respectively facing perpendicularly upward. The center of a horizontally installed turntable 49 is affixed to the rotating shaft 48 of each motor 47.

A total of three support pins 50, 50, 50 are respectively affixed at mutual phase differentials of 120 degrees along the periphery on the sides on the upper surface of each turntable 49. A taper section 51 is formed on the support surface for supporting the wafer 1 of each support pin 50. The taper section 51 serves to self align the rotation center of the turntable 49 with the center of the wafer 1. Moreover, by supporting a small section of the periphery on the bottom side of the wafer 1, the taper section 51 functions to prevent particles from adhering to the rear surface of the wafer 1.

As shown in FIG. 3, an air cylinder 52 is installed upward with a piston rod 53 mounted vertically along the center line inside the machine stand 41. The top end of the piston rod 53 protrudes in the space between the shelf plate 46 on the bottommost stage and the upper surface of the machine stand 41. A horizontally installed base 54 is clamped to the top end of the piston rod 53. The air cylinder 52 raises and lowers the base 54.

A total of three scoop poles 55, 55, 55 are respectively affixed perpendicularly at phase differentials of 120 degrees along the periphery on the upper side of the base 54. Each of the scoop poles 55 is inserted through each insertion hole 56 formed on each shelf plate 46, and protrudes upward from the shelf plates 46 on the topmost stage.

Scoop support pins 57 are provided horizontally at equally space intervals along the perpendicular in each of the scoop poles 55. Each of the scoop support pins 57 protrudes slightly towards the rotation center of the wafers 1. The tip of each scoop support pin 57 engages from the bottom with a small section of the periphery on the bottom surface of the wafer 1, so as to scoop up the wafer 1 horizontally. The wafer support surface on the each of the scoop support pins 57 forms the wafer supporting surface with a slight taper angle.

As shown in FIG. 2, two support poles 58 and 59 are affixed perpendicularly at mutually adjacent positions on the side opposite the wafer load/unload opening 43 on the upper side of the machine stand 41.

Transmission type sensors 60, 60, 60, 60, 60 for a total of five notch detectors 44 corresponding to each turntable 49 are each installed horizontally on one support pole 58.

Reflective type sensors 70, 70, 70, 70, 70 for the five notch detectors 44 corresponding to each turntable 49 are each installed horizontally on the other support pole 59.

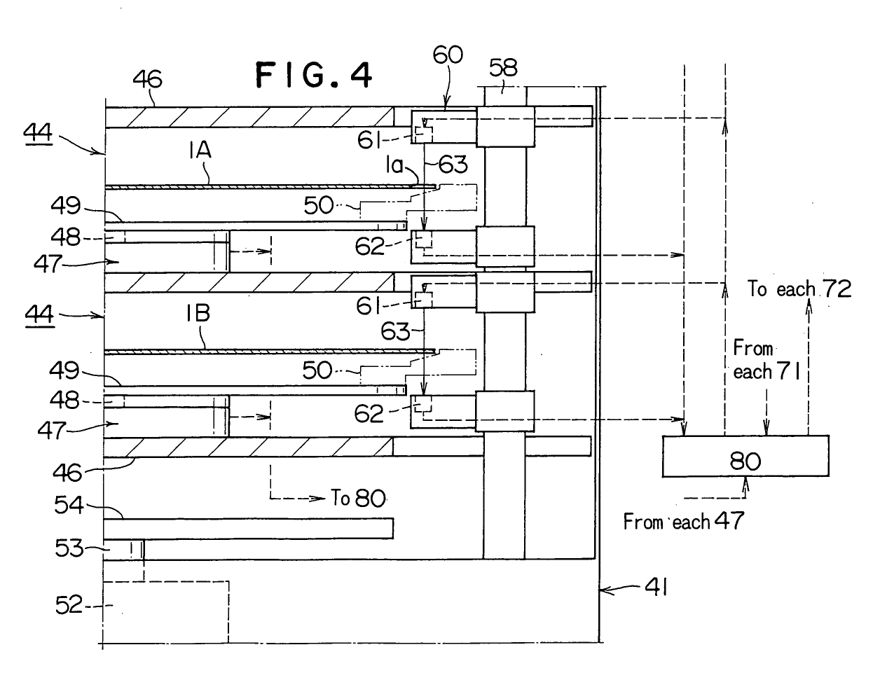

As shown in FIG. 4, the transmission type sensor 60 for each notch detector 44 contains a transmission type light emitter unit 61 and a transmission type light receiver unit 62.

The transmission type light emitter unit 61 and the transmission type light receiver unit 62 are at upper and lower positions of the wafer 1 supported on the turntable 49. The transmission type light emitter unit 61 and the transmission type light receiver unit 62 are positioned facing each other within the range of the notch 1a formed on the periphery of the wafer 1, and are respectively supported by the support poles 58.

Also, the transmission type light emitter unit 61 and the transmission type light receiver unit 62 are respectively installed so as not to interfere with the three support pins 50, 50, 50 and the turntable 49 during the rotation of the wafer 1. The transmission type light emitter unit 61 irradiates detection light 63 towards the transmission type light receiver unit 62. The transmission type light receiver unit 62 sends electrical signals to a controller 80 when receiving the detection light 63.

The sensor width of the transmission type sensor 60 used in this embodiment is five millimeters so that the sensor position of the transmission type sensor 60 is set at position 2.5±0.5 millimeters from the edge of the wafer 1.

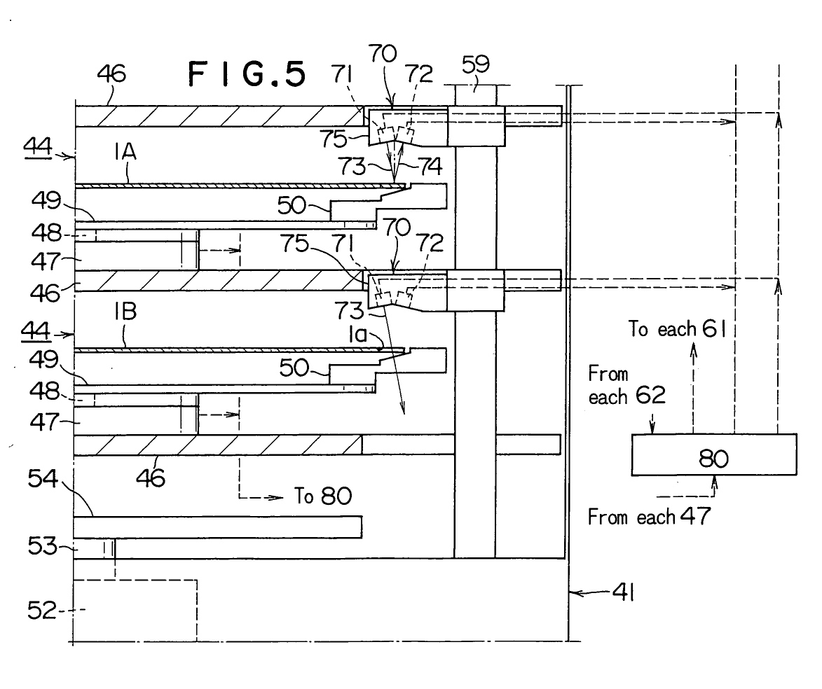

As shown in FIG. 5, the reflective type sensor 70 of each notch detector 44 includes a reflective type light emitter unit 71 and a reflective type light receiver unit 72. The reflective type light emitter unit 71 and the reflective type light receiver unit 72 are contained in one holder 75. The holder 75 of the reflective type sensor 70 is installed so as not to interfere with the three support pins 50, 50, 50 and the turntable 49 during rotation of the wafer 1 and is supported on the support pole 59.

The reflective type light emitter unit 71 and the reflective type light receiver unit 72 are installed as described next.

The reflective type light emitter unit 71 is installed above the wafer 1 supported on the turntable 49, and installed at a position where the emitted light can reach the notch 1a formed on the peripheral edge of the wafer 1. The emitted light passes through or is reflected at the notch 1a. The reflective type light receiver unit 72 is installed at a position for receiving the reflected light.

The reflective type light emitter unit 71 irradiates detection light 73 towards the surface of the peripheral edge of the wafer 1. The reflective type light receiver unit 72 sends electrical signals to the controller 80 after receiving the reflected light 74 when the detection light 73 is reflected from the surface of wafer 1.

The sensor width of the reflective type sensor 70 used in this embodiment is six millimeters so that the sensor position of the reflective type sensor 70 is set at position 3.0±0.5 millimeters from the edge of the wafer 1.

As shown in FIG. 4 and FIG. 5, an angular signal from a rotation position detection encoder (not shown in drawing) of each motor 47 is input to the controller 80.

Though not shown in detail in the drawing, the transmission type light emitter unit 61 and the transmission type light receiver unit 62 of the transmission type sensor 60; and the reflective type light emitter unit 71 and the reflective type light receiver unit 72 of the reflective type sensor 70 are made up of multiple optical fibers and amplifiers, etc.

The controller 80 is programmed by utilizing software in hardware such as panel computers, personal computers and microcomputers.

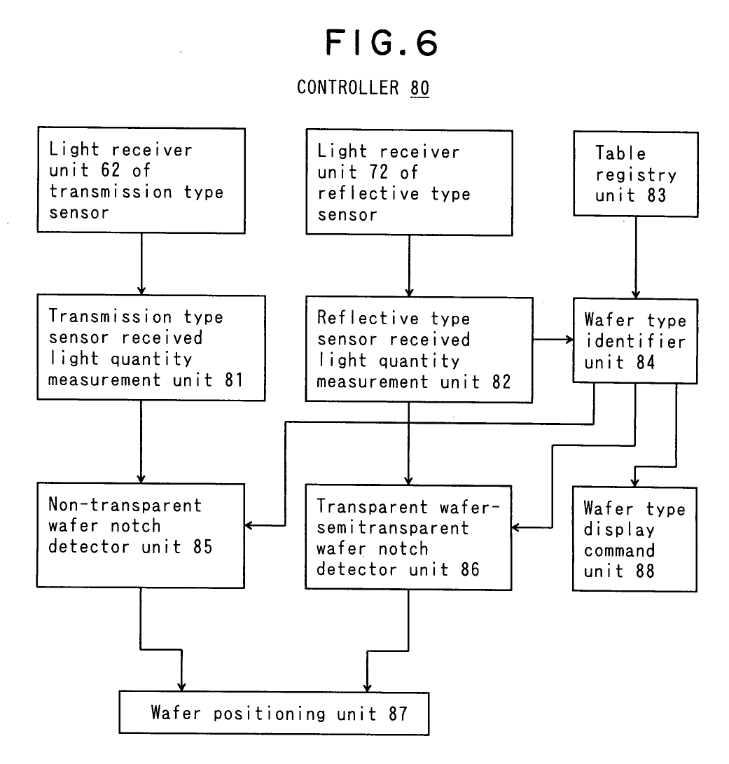

As shown in FIG. 6, the controller 80 includes a transmission type sensor received light quantity measurement unit 81 for measuring the received light quantity at the transmission type sensor by way of electrical signals from the transmission type light receiver unit 62 of the transmission type sensor 60, and a reflective type sensor received light quantity measurement unit 82 for measuring the received light quantity at the reflective type sensor by way of electrical signals from the reflective type light receiver unit 72 of the reflective type sensor 70 and, a table registry unit 83 where tables required for identifying the wafer type are registered and, a wafer type identifier unit 84 for comparing the received light quantity from the reflective type sensor received light quantity measurement unit 82 and the light quantity range registered in the table registry unit 83.

A non-transparent wafer notch detector unit 85 and a transparent wafer-semitransparent wafer notch detector unit 86 are connected to the identifier unit 84.

The non-transparent wafer notch detector unit 85 detects the notch position of the non-transparent wafer based on the time-base data from the transmission type sensor received light quantity measurement unit 81, and the angular signal (time-based data) from the motor 47.

The transparent wafer-semitransparent wafer notch detector unit 86 detects the notch position of transparent wafers and semitransparent wafers based on the time-based data from the reflective type sensor received light quantity measurement unit 82 and the angular signal (time-based data) from the motor 47.

The non-transparent wafer notch detector unit 85 and the transparent wafer-semitransparent wafer notch detector unit 86 are connected to a wafer positioning unit 87. The wafer positioning unit 87 aligns the notch positions on the five wafers based on the notch detection results from the non-transparent wafer notch detector unit 85 and the transparent wafer-semitransparent wafer notch detector unit 86.

A wafer type display command unit 88 is connected to the identifier unit 84. The wafer type display command unit 88 outputs instructions to the display unit (not shown in drawing) on the batch type CVD apparatus, to display the wafer type that was identified by the identifier unit 84.

The table registry unit 83 contains a pre-registered table as shown in the following Table 1, with results from finding the received light quantity at the reflective type sensor 70 for silicon wafers that are non-transparent wafers, quartz wafers that are transparent wafers and silicon carbide wafers that are semitransparent wafers.

TABLE 1

| | RECEIVED LIGHT | RECEIVED LIGHT |
|---|---|---|
| | QUANTITY | QUANTITY |
| WAFER TYPES | (maximum value) | (minimum value) |
| Silicon wafers | 3920 | 3650 |
| (non-transparent) | | |
| Quartz wafers | 800 | 660 |
| (transparent) | | |
| Silicon carbide | 260 | 240 |
| wafers | | |
| (semi-transparent) | | |

The value measured on each wafer type as the received light quantity, fluctuates due to differentials such as in the optical fiber and the amplifier type (model) of the reflective type sensor 70. The received light quantity values in Table 1 should therefore preferably be found by experiment using an actual reflective type sensor 70.

Data for this Table 1 was found in advance by experiment under the following conditions.

A red LED (light emitting diode) was utilized as the light emission source.

The distance between the reflective type sensor 70 and the wafer was set at 36 millimeters.

The measurement range for the received light quantity was 0 (minimum) to 4,000 (maximum: saturation).

The received light quantity under the reference load was 3800 on a silicon wafer, and the received light quantity was 60 during no load (no wafer).

Multiple wafers of the same type and multiple locations were each measured, the average value taken from those measurements was rounded off to the first decimal point, and that value then used in the table.

The method for operating the above described CVD apparatus is described using the case where forming film on silicon wafers (non-transparent), quartz wafers (transparent), and silicon carbide wafers (semi-transparent).

When the pod 2 is supplied to the pod stage 14 as shown in FIG. 1, the front shutter 13 opens the pod load/unload opening 12. The pod transfer device 16 scoops up the pod 2 on the pod stage 14, and loads the pod 2 into the interior of the case 11 from the pod loader/unload opening 12.

The pod transfer device 16 automatically transfers the pod 2 that was carried in, to the specified shelf plate of the rotating pod rack 15 where the pod 2 is taken and temporarily stored.

The pod transfer device 16 scoops the pod 2 that was temporarily stored on the specified shelf plate of the rotating pod rack 15, and the pod 2 is transferred to the pod opener 21 and loaded on the mounting stand 22.

When the pod 2 is placed onto the mounting stand 22, the pod opener 21 pushes the open side of the pod 2 into the open edge of the wafer load/unload opening on the front side of the standby chamber case 18. The cap fitter/remover mechanism 23 removes the cap to open the wafer load/unload opening.

When the pod opener 21 releases the wafer load/unload opening of the pod 2, the wafer transfer device 35 inserts the five tweezers 36 into the pod 2, scoops up the five wafers 1 together, and then loads the five wafers 1 into the standby chamber 17 from the wafer load/unload opening by retracting the five tweezers 36.

The wafer transfer device 35 that loaded the five wafers 1 into the standby chamber 17 by way of the tweezers 36, transfers the five wafers 1 into the wafer load/unload opening 43 of the wafer positioning device 40.

In the wafer positioning device 40 on the other hand, the three scoop poles 55, 55, 55 and the base 54 are raised to the uppermost position by the piston rod 53 via the air cylinder 52 so that each of the scoop support pins 57 installed respectively between the five-stage shelf plates 46 on each of the scoop poles 55 are raised up to a position above each turntable 49 serving as the wafer transfer position.

When the five tweezers 36 of the wafer transfer device 35 are inserted in this state into the wafer load/unload opening 43 of the wafer positioning device 40, the five wafers 1 are loaded to just slightly above each of the five-stage support pins 57.

When the tweezers 36 of the wafer transfer device 35 are lowered slightly in this state, the wafers 1 on the five tweezers 36 are respectively transferred from above the five tweezers 36 onto each of the five-stage support pins 57.

After the five tweezers 36 that transferred the wafers 1 are extracted from the wafer load/unload opening 43 of the wafer positioning device 40, the three scoop holes 55, 55, 55 and the base 54 are lowered by the piston rod 53 via the air cylinder 52 to the lower limit position serving as the standby position. The five wafers 1 supported from below on each of the scoop support pins 57 are in this way respectively placed onto the each of the support pins 50 of the five-stage turntables 49.

After the five-stage turntables 49 receive each of the five wafers 1, the wafer positioning device 40 rotates the five-stage turntables 49 by the five motors 47 to rotate the five wafers 1.

During this rotation, the controller 80 of the wafer positioning device 40 control to emit the detection light 63 from the transmission type light emitter unit 61 of each transmission type sensor 60 as shown in FIG. 4 and FIG. 5, and to emit the detection light 73 from the reflective type light emitter unit 71 of each reflective type sensor 70. The controller 80 in this way acquires each of the received light electrical signals from the transmission type light receiver unit 62 of the transmission type sensor 60, and the received light electrical signals from the reflective type light receiver unit 72 of the reflective type sensor 70.

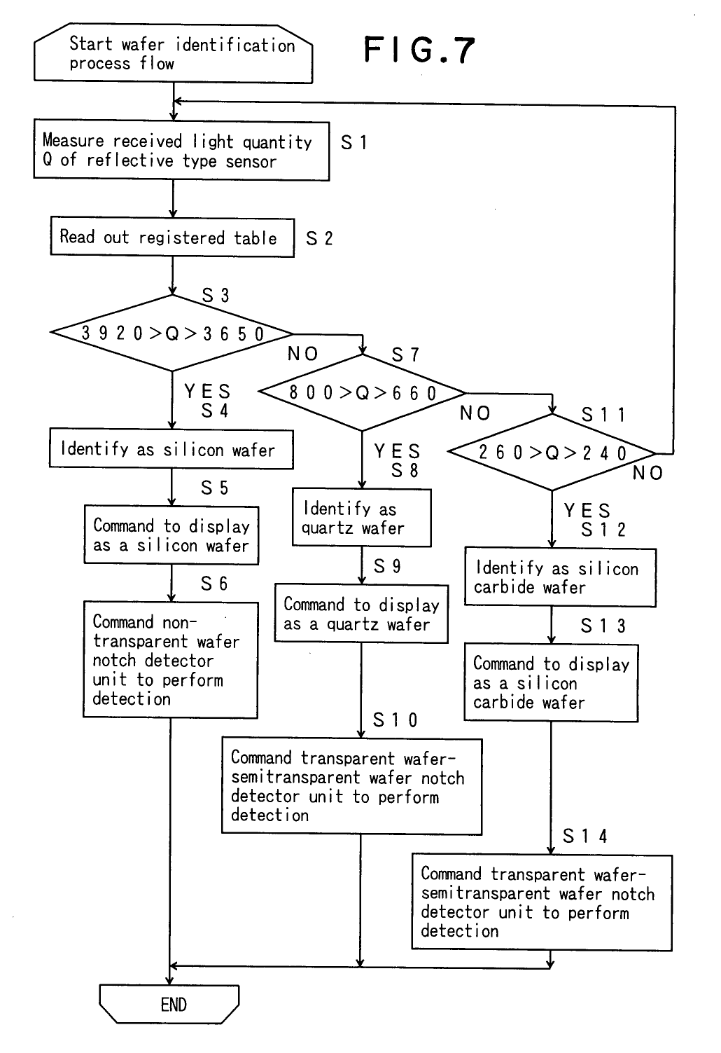

The controller 80 next executes the wafer identification process flow shown in FIG. 7 to automatically identify whether the wafer 1 loaded into the wafer positioning device 40 is a silicon wafer, a quartz wafer, or a silicon carbide wafer.

In the first step S1 shown in FIG. 7, the reflective type sensor received light quantity measurement unit 82 of the controller 80 measures the received light quantity Q in the received light electrical signals from the reflective type light receiver unit 72 of the reflective type sensor 70.

In the second step S2, the controller 80 reads out the pre-registered tables from the table registry unit 83.

In the third step S3, the identifier unit 84 of the controller 80 compares the received light quantity range for silicon wafers among the tables loaded from the table registry unit 83, with the received light quantity Q from the reflective type sensor received light quantity measurement unit 82. The identifier unit 84 in other words decides whether or not the received light quantity Q from the reflective type sensor received light quantity measurement unit 82 is within a range exceeding 3650 and below 3920.

If the received light quantity Q from the reflective type sensor received light quantity measurement unit 82 is within a range exceeding 3650 and below 3920, then the identifier unit 84 decides that the “Wafer for identification is a silicon wafer” (fourth step S4).

The identifier unit 84 sends this identification result to the wafer type display command unit 88. The wafer type display command unit 88 sends a “command to display that the wafer for identification is a silicon wafer” to the batch type CVD apparatus display unit (fifth step S5).

The identifier unit 84 moreover sends the identification result that “Wafer for identification is a silicon wafer” to the non-transparent wafer notch detector unit 85 and instructs the non-transparent wafer notch detector unit 85 to perform notch detection (sixth step S6).

However, in the third step S3, if the received light quantity Q from the reflective type sensor received light quantity measurement unit 82 is not within a range exceeding 3650 and below 3920, then the identifier unit 84 shifts the process flow forward to the seventh step S7.

In the seventh step S7, the identifier unit 84 of the controller 80 compares the received light quantity Q from the reflective type sensor received light quantity measurement unit 82, with the received light quantity range for quartz wafers among the tables loaded from the table registry unit 83. The identifier unit 84 in other words decides whether or not the received light quantity Q from the reflective type sensor received light quantity measurement unit 82 is within a range exceeding 660 and below 800.

If the received light quantity Q from the reflective type sensor received light quantity measurement unit 82 is within a range exceeding 660 and below 800, then the identifier unit 84 identifies that the “Wafer for identification is a quartz wafer” (eighth step S8).

The identifier unit 84 sends this identification result to the wafer type display command unit 88. The wafer type display command unit 88 sends the “command to display that the wafer for identification is a quartz wafer” to the batch type CVD apparatus display unit (ninth step S9).

The identifier unit 84 moreover sends the identification result that the “Wafer for identification is a quartz wafer” to the transparent wafer-semitransparent wafer notch detector unit 86, and instructs the transparent wafer-semitransparent wafer notch detector unit 86 to perform notch detection (tenth step S10).

However, in the seventh step S7 when the received light quantity Q from the reflective type sensor received light quantity measurement unit 82 is not within a range exceeding 660 and below 800, then the identifier unit 84 shifts the process flow forward to the eleventh step S11.

In the eleventh step S11, the identifier unit 84 of the controller 80 compares the received light quantity Q from the reflective type sensor received light quantity measurement unit 82, with the received light quantity range for silicon carbide wafers among the tables loaded from the table registry unit 83. The identifier unit 84 in other words decides whether or not the received light quantity Q from the reflective type sensor received light quantity measurement unit 82 is within a range exceeding 240 and below 260.

If the received light quantity Q from the reflective type sensor received light quantity measurement unit 82 is within a range exceeding 240 and below 260, then the identifier unit 84 identifies that the “Wafer for identification is a silicon carbide wafer” (twelfth step S12).

The identifier unit 84 sends this identification result to the wafer type display command unit 88. The wafer type display command unit 88 sends a “command to display that the wafer for identification is a silicon carbide wafer” to the batch type CVD apparatus display unit (thirteenth step S13).

The identifier unit 84 further sends the identification result that the “Wafer for identification is a silicon carbide wafer” to the transparent wafer-semitransparent wafer notch detector unit 86 and instructs the transparent wafer-semitransparent wafer notch detector unit 86 to perform notch detection (fourteenth step S14).

However, in the eleventh step S11 when the received light quantity Q from the reflective type sensor received light quantity measurement unit 82 is not within a range exceeding 240 and below 260, then the identifier unit 84 returns the process flow to the first step S1, and re-performs the wafer identification process flow.

In this case, the operation of acquiring received light electrical signals from the reflective type light receiver unit 72 of the reflective type sensor 70 is preferably re-performed.

The controller 80 issues an error alarm if the number of retries reaches a preset count.

Then, in the sixth step S6, the non-transparent wafer notch detector unit 85 that received the instruction to detect notches on silicon wafers, detects the notch position on transparent wafers based on angular signals from the motor 47 and electrical signals from the transmission type light receiver unit 62 of the transmission type sensor 60, and sends the detection results to the wafer positioning unit 87.

In the tenth step S10 or the fourteenth step S14, the transparent wafer-semitransparent wafer notch detector unit 86 that received the instruction to detect the notch on quartz wafers (transparent wafers) or silicon carbide wafers (semi-transparent wafers), detects the notch position on quartz wafers or silicon carbide wafers based on angular signals from the motor 47 and electrical signals from the reflective type light receiver unit 72 of the reflective type sensor 70, and sends the detection results to the wafer positioning unit 87.

If for example the silicon wafers that are non-transparent wafers, are mixed with quartz wafers that are transparent wafers, and assuming as shown in FIG. 4 and FIG. 5, that in the wafer positioning device 40 the wafer at the first stage from the bottom is a quartz wafer 1B, and the wafer at the second stage from the bottom is a silicon wafer 1A; then the transparent wafer-semitransparent wafer notch detector unit 86 uses the reflective type sensor 70 to detect the notch 1a on the quartz wafer 1B at the first stage from the bottom; and the non-transparent wafer notch detector unit 85 uses the transmission type sensor 60 to detect the notch 1a on the silicon wafer 1A at the second stage from the bottom.

The wafer positioning device 40 can array the notch 1a positions of all five wafers 1 in this way, even if quartz wafers 1B are mixed in with the silicon wafers 1A, since the transmission type sensor 60 and the reflective type sensor 70 are respectively installed within all five notch detector units of the wafer positioning device 40, and the notch 1a positions of all wafers carried into the five-stage turntables 49 of the wafer positioning device 40 can be acquired by the wafer positioning unit 87.

When the wafer positioning device 40 arrays the mutual notch 1a positions of all five wafers, the five wafers 1 are carried out from the wafer positioning device 40 in an operation that is the reverse of the loading operation described above for the five tweezers 36 of the wafer transfer device 35.

Next, the wafer transfer device 35 transfers the five tweezers 36 that carried out the five wafers 1 from the wafer positioning device 40, to the boat 34, and transfers the five wafers 1 in one batch to the boat 34.

The standby chamber 17 is load-locked when a pre-specified number of (for example, 25 wafers) wafers 1 are charged into the boat 34, by repeating the step of loading of the five wafers 1 from the pod 2 to the wafer positioning device 40; the step of positioning the wafers in the wafer positioning device 40, and the step of transferring the wafers from the wafer positioning device 40 to the boat 34.

When the pre-specified number of wafers 1 are charged into the boat 34, the boat elevator 30 raises the boat 34 and it is carried into the processing chamber 26 of the process tube 25.

When the boat 34 reaches the upper limit, the periphery on the upper side of the seal cap 33 holding the boat 34 shuts the process tube 25 into a sealed state so that the processing chamber 26 is closed airtight.

While the processing chamber 26 of the process tube 25 is closed in an airtight state, the processing chamber 26 atmosphere is evacuated to the specified pressure by the exhaust pipe 28, and then heated to a specified temperature by the heater unit 24, and a specified material gas is supplied at just the specified flow rate via the gas feed pipe 27.

The desired film matching the preset processing conditions is in this way formed on the wafer 1.

When the specified processing time has elapsed, the boat elevator 30 lowers the boat 34 so that the boat 34 holding the now processed wafers 1 is carried out to the wafer transfer position.

After the boat 34 is carried out to the wafer transfer position, the wafer transfer device 35 receives the now processed wafers 1 on the boat 34 via the five tweezers 36 one at a time to discharge them.

The wafer transfer device 35 next transfers the five wafers 1 to the pod 2 that was released by the pod opener 21, and stores them in the pod 2.

When transfer of the 25 wafers 1 in the boat 34 to the empty pod 2 for storage is completed by repeating the steps of discharging the now processed wafers 1 and storing the wafers 1 in the pod 2; the cap fitter/remover mechanism 23 fits the cap on the pod 2. The pod transfer device 16 then transfers the pod from the mounting stand 22 of the pod opener 21 to the specified shelf plate of the rotating pod rack 15 to temporarily store the pod.

Afterwards, the pod transfer device 16 transports the pod 2 holding the processed wafers 1 from the rotating pod rack 15 to the pod load/unload opening 12, and the pod 2 is then carried out from the pod load/unload opening 12 to outside the case 11 and placed on the pod stage 14. The pod 2 placed on the pod stage 14 is transferred to the next process by an inter-process transfer device.

The batch type CVD apparatus 10 batch processes the wafers 1 by repeating the aforementioned actions.

The aforementioned embodiment renders the following effects.

1) Whether the wafer loaded into the batch type CVD apparatus is a silicon wafer or a quartz wafer or a silicon carbide wafer can be identified by comparing the reflective type sensor received light quantity with the received light quantity range from the table found in advance by experiment so that the task of identifying in advance the type of the wafer loaded into the batch type CVD apparatus by the operator of the batch type CVD apparatus or the host controller can be omitted, the burden on the operator and host controller can be lightened, and mistaken data entries can be prevented.

2) A reflective type sensor or a transmission type sensor is utilized as needed on the wafer loaded in the wafer positioning device by identifying automatically whether the wafer loaded into the wafer positioning device is a non-transparent wafer (silicon wafer) or a transparent wafer (quartz wafer) or a semi-transparent wafer (silicon carbide wafer) so that the notch of the wafer can be detected.

3) The wafer positioning unit can acquire the notch positions for all wafers loaded on the five-stage turntables in the wafer positioning device because transmission type sensors and reflective type sensors are installed respectively in all five notch detectors of the wafer positioning device so that the notch positions of all five wafers can be arrayed, even in cases where silicon wafers that are non-transparent wafers, and quartz wafers that are transparent wafers and silicon carbide wafers that are semi-transparent wafers are all mixed in the wafer positioning device.

4) The wafer type identified by the identifier unit is send to a wafer type display command unit, and the type of wafer for identification is displayed on the display unit of the batch type CVD apparatus and therefore allows the batch type CVD apparatus operator and the host controller to confirm the type of wafer, so that all wafer defects caused by mistaken controller or operator entries can be prevented.

The present invention is not limited to the above embodiment and needless to say changes and adaptations of various types not departing from the scope or spirit of this invention are permitted.

In the above embodiment for example, a reflective type sensor was utilized for identifying the wafer type. However, a transmission type sensor may also be utilized to identify the wafer type.

In that case, transparent wafers such as quartz wafers cannot be identified since the light emitted from the transmission type sensor will transmit through them so the detector will mistakenly judge that no wafer is present. However, non-transparent wafers such as silicon wafers, and semi-transparent wafers such as silicon carbide wafers can be identified.

Therefore, the detection accuracy can be improved by utilizing a structure including both a reflective type sensor and a transmission type sensor for identifying the wafer type.

In the above embodiment, a reflective type sensor was utilized for identifying the wafer type. However, experiments made in measuring the received light quantity of reflective type sensors on silicon wafers formed with different types of films resulted in contriving the table as shown below in Table 2. This table may be utilized to identify film types formed on the wafer.

TABLE 2

| | RECEIVED LIGHT | RECEIVED LIGHT |
|---|---|---|
| | QUANTITY | QUANTITY |
| FILM TYPES | (maximum value) | (minimum value) |
| Silicon oxide | 1360 | 1000 |
| film | | |
| (HTO) | | |
| Silicon nitride | 300 | 90 |
| film | | |
| Silicon oxide | 2270 | 2040 |
| film | | |
| (PYRO) | | |

Moreover, experiments made in measuring the received light quantity of reflective type sensors on silicon wafers formed with films with different thicknesses resulted in contriving the table as shown below in Table 3. This table may be utilized to identify film thicknesses formed on the wafer.

TABLE 3

| | RECEIVED LIGHT | RECEIVED LIGHT |
|---|---|---|
| | QUANTITY | QUANTITY |
| FILM TYPES | (maximum value) | (minimum value) |
| B type film: | 410 | 300 |
| thick film | | |
| (dark blue color) | | |
| B type film: | 1370 | 1220 |
| thin film | | |
| (blue color) | | |
| A type film: | 1020 | 970 |
| thick film (red | | |
| yellow color) | | |
| A type film: | 1680 | 1590 |
| thin film | | |
| (yellow color) | | |

The light emission source is not limited to red LED, and for example blue LED, green LED, red laser semiconductor devices, blue laser semiconductor device as well as insulating laser semiconductor devices may also be utilized.

Moreover, these optical devices may be jointly used so that the light quantity range with the largest threshold may be selected for identical wafer types or identical film types as well as identical film thicknesses to boost the identification accuracy.

The wafer positioning device is not limited to containing five notch detector units and may utilize one unit or two to four units, or 6 units or more of notch detectors.

The controller and the substrate detector unit for identifying the wafer need not be installed into the wafer positioning device, and may be installed as isolated units.

In the above embodiment, a batch type vertical diffusion CVD apparatus was described. However, the present invention is not limited to that apparatus and can be generally applied to semiconductor manufacturing apparatus.

Typical aspects for the invention as disclosed in this specification are as follows.

(1) A semiconductor manufacturing apparatus comprising:

a substrate transfer device for transferring a substrate;

a substrate detector unit including a light emitter unit for emitting light onto the substrate and a light receiver unit for receiving the light to detect the substrate transferred by the substrate transfer device; and

a controller for receiving the received light quantity data from the light receiver unit, wherein

multiple, mutually non-overlapping light quantity ranges are pre-registered in the controller, and when light emitted from the light emitter unit reaches the light receiver unit by way of the substrate, the controller identifies which of the pre-registered light quantity ranges is the received light quantity, and outputs a command according to the identified light quantity range.

(2) A semiconductor manufacturing apparatus comprising:

a processing chamber for processing a substrate;

a substrate detector unit including a light emitter unit for emitting light onto the substrate and a light receiver unit for receiving the light to detect the substrate prior to loading the substrate into the processing chamber; and

a controller for receiving the received light quantity data from the light receiver unit, wherein

multiple, mutually non-overlapping light quantity ranges are pre-registered in the controller, and when light emitted from the light emitter unit reaches the light receiver unit by way of the substrate, the controller identifies which of the pre-registered light quantity ranges is the received light quantity, and outputs a command according to the identified light quantity range.

(3) A semiconductor manufacturing apparatus according to the first (1) aspect or the second (2) aspect, wherein the substrate detector unit is a reflective type sensor including the light emitter unit and the light receiver unit.

(4) A semiconductor manufacturing apparatus according to the first (1) aspect or the second (2) aspect, wherein the substrate detector unit is a transmission type sensor including the light emitter unit and the light receiver unit.

(5) A semiconductor manufacturing apparatus according to the first (1) aspect or the second (2) aspect, wherein when detecting the notch position of the substrate identified in the substrate detector unit with the substrate rotated after identifying the substrate type, the command according to the identified light quantity range is a command to select use of a reflective type sensor or a transmission type sensor for detecting the notch.

(6) A semiconductor manufacturing apparatus according to the first (1) aspect or the second (2) aspect, wherein the command according to the identified light quantity range is a command to a control display unit to display the wafer type matching the detected light quantity range.

(7) A semiconductor manufacturing apparatus according to the first (1) aspect or the second (2) aspect, wherein the substrate detector unit includes a reflective type sensor and a transmission type sensor to detect the substrate.

(8) A semiconductor manufacturing apparatus according to the first (1) aspect or the second (2) aspect, wherein the substrate is any one of non-transparent substrate, semitransparent substrate and transparent substrate.

(9) A semiconductor manufacturing apparatus according to the first (1) aspect or the second (2) aspect, wherein among the received light quantity data for any one of the non-transparent substrate, semitransparent substrate and transparent substrate, the multiple received light quantity data is at least two or more light quantity data from among the non-transparent substrate, semitransparent substrate and transparent substrate.

(10) A semiconductor manufacturing apparatus according to the first (1) aspect or the second (2) aspect, wherein the multiple received light quantity data is received light quantity data for two or more different film types.

(11) A semiconductor manufacturing apparatus according to the first (1) aspect or the second (2) aspect, wherein the multiple received light quantity data is received light quantity data for two or more different film thicknesses.

(12) A method for manufacturing a semiconductor device utilizing a semiconductor manufacturing apparatus according to the second (2) aspect, comprising:

a step prior to loading a substrate into a processing chamber, in which the controller where the multiple, mutually non-overlapping light quantity ranges are pre-registered, controls to emit light from the light emitter unit towards the substrate transferred by the substrate transfer device, and the emitted light reaches the light receiver unit by way of the substrate;

a step where the controller identifies which of the pre-registered light quantity ranges is the light quantity received by the light receiver unit, and outputs a command according to the identified light quantity range;

a step of loading the substrate into the processing chamber;

a step of supplying gas from a gas supply pipe to the substrate loaded into the processing chamber;

a step of processing the substrate in the processing chamber; and

a step of unloading the substrate from the processing chamber after processing.

(13) A manufacturing method for a semiconductor device comprising:

a step of transferring a substrate to a substrate detector unit;

a step in which a controller where multiple, mutually non-overlapping light quantity ranges are pre-registered, controls to emit light from a light emitter unit towards the substrate transferred by a substrate transfer device, and the emitted light reaches a light receiver unit by way of the substrate;

a step where the controller identifies which of the pre-registered light quantity ranges is the light quantity received by the light receiver unit, and outputs a command according to the identified light quantity range;

a step of loading the substrate into a processing chamber;

a step of supplying gas from a gas supply pipe to the substrate loaded into the processing chamber;

a step of processing the substrate in the processing chamber; and

a step of unloading the substrate from the processing chamber after processing.

(14) A manufacturing method for a semiconductor device according to the thirteenth (13) aspect, wherein the controller outputs a command according to the light quantity range, and a substrate positioning unit that received the command arrays the substrate position.

1. A semiconductor manufacturing apparatus comprising:
a substrate transfer device for transferring a substrate;
a substrate detector unit including a light emitter unit for emitting light onto the substrate and a light receiver unit for receiving the light to detect the substrate transferred by the substrate transfer device; and
a controller for receiving the received light quantity data from the light receiver unit, wherein
multiple, mutually non-overlapping light quantity ranges are pre-registered in the controller, and when light emitted from the light emitter unit reaches the light receiver unit by way of the substrate, the controller identifies which of the pre-registered light quantity ranges is the received light quantity, and outputs a command according to the identified light quantity range.

2. A semiconductor manufacturing apparatus comprising:
a processing chamber for processing a substrate;
a substrate detector unit including a light emitter unit for emitting light onto the substrate and a light receiver unit for receiving the light to detect the substrate prior to loading the substrate into the processing chamber; and
a controller for receiving the received light quantity data from the light receiver unit, wherein
multiple, mutually non-overlapping light quantity ranges are pre-registered in the controller, and when light emitted from the light emitter unit reaches the light receiver unit by way of the substrate, the controller identifies which of the pre-registered light quantity ranges is the received light quantity, and outputs a command according to the identified light quantity range.

3. A semiconductor manufacturing apparatus according to claim 1, wherein the substrate detector unit is a reflective type sensor including the light emitter unit and the light receiver unit.

4. A semiconductor manufacturing apparatus according to claim 1, wherein the substrate detector unit is a transmission type sensor including the light emitter unit and the light receiver unit.

5. A semiconductor manufacturing apparatus according to claim 1, wherein when detecting the notch position of the substrate identified in the substrate detector unit with the substrate rotated after identifying the substrate type, the command according to the identified light quantity range is a command to select use of a reflective type sensor or a transmission type sensor for detecting the notch.

6. A semiconductor manufacturing apparatus according to claim 1, wherein the command according to the identified light quantity range is a command to a control display unit to display the wafer type matching the detected light quantity range.

7. A semiconductor manufacturing apparatus according to claim 1, wherein the substrate detector unit includes a reflective type sensor and a transmission type sensor to detect the substrate.

8. A semiconductor manufacturing apparatus according to claim 1, wherein the substrate is any one of non-transparent substrate, semitransparent substrate and transparent substrate.

9. A semiconductor manufacturing apparatus according to claim 1, wherein among the received light quantity data for any one of the non-transparent substrate, semitransparent substrate and transparent substrate, the multiple received light quantity data is at least two or more light quantity data from among the non-transparent substrate, semitransparent substrate and transparent substrate.

10. A semiconductor manufacturing apparatus according to claim 1, wherein the multiple received light quantity data is received light quantity data for two or more different film types.

11. A semiconductor manufacturing apparatus according to claim 1, wherein the multiple received light quantity data is received light quantity data for two or more different film thicknesses.

12. A method for manufacturing a semiconductor device utilizing a semiconductor manufacturing apparatus according to claim 2, comprising:
a step prior to loading a substrate into a processing chamber, in which the controller where the multiple, mutually non-overlapping light quantity ranges are pre-registered, controls to emit light from the light emitter unit towards the substrate transferred by the substrate transfer device, and the emitted light reaches the light receiver unit by way of the substrate;
a step where the controller identifies which of the pre-registered light quantity ranges is the light quantity received by the light receiver unit, and outputs a command according to the identified light quantity range;
a step of loading the substrate into the processing chamber;
a step of supplying gas from a gas supply pipe to the substrate loaded into the processing chamber;
a step of processing the substrate in the processing chamber; and
a step of unloading the substrate from the processing chamber after processing.

13. A manufacturing method for a semiconductor device comprising:
a step of transferring a substrate to a substrate detector unit;
a step in which a controller where multiple, mutually non-overlapping light quantity ranges are pre-registered, controls to emit light from a light emitter unit towards the substrate transferred by a substrate transfer device, and the emitted light reaches a light receiver unit by way of the substrate;
a step where the controller identifies which of the pre-registered light quantity ranges is the light quantity received by the light receiver unit, and outputs a command according to the identified light quantity range;
a step of loading the substrate into a processing chamber;
a step of supplying gas from a gas supply pipe to the substrate loaded into the processing chamber;
a step of processing the substrate in the processing chamber; and
a step of unloading the substrate from the processing chamber after processing.

14. A manufacturing method for a semiconductor device according to claim 13, wherein the controller outputs a command according to the light quantity range, and a substrate positioning unit that received the command arrays the substrate position.
